(19) United States
(12) Patent Application Publication
(10) Pub. No.: US 2019/0035720 A1
(43) Pub. Date: Jan. 31, 2019

(54) STRESS DISTRIBUTION INTERPOSER FOR MITIGATING SUBSTRATE CRACKING

(71) Applicant: Intel Corporation, Santa Clara, CA (US)

(72) Inventors: Min-Tih LAI, Orangevale, CA (US); Yuhong CAI, Folsom, CA (US)

(73) Assignee: Intel Corporation, Santa Clara, CA (US)

(21) Appl. No.: 16/070,482

(22) PCT Filed: Apr. 1, 2016
(86) PCT No.: PCT/US16/25747

§ 371 Date: Jul. 16, 2018

(51) Int. Cl. H01L 23/498; H05K 3/34

(52) U.S. Cl. CPC H01L 23/49838; H01L 23/3738; H05K 3/3436; H01L 23/49816

(57) ABSTRACT

In accordance with disclosed embodiments, there are provided methods, systems, and apparatuses for implementing a stress distribution interposer for mitigating substrate cracking. For instance, in accordance with one embodiment, there is an apparatus having therein: a substrate having electrical traces therein; a functional semiconductor die electrically interfaced to the electrical traces of the substrate; an interposer bonded at a bottom surface to the substrate and bonded at a top surface to the functional semiconductor die; and in which the interposer includes edges with a coefficient of thermal expansion and modulus which is between a coefficient of thermal expansion and modulus of the substrate and a coefficient of thermal expansion and modulus of the functional semiconductor die. Other related embodiments are disclosed.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### TECHNICAL FIELD

The subject matter described herein relates generally to the field of semiconductor and electronics manufacturing, and more particularly, to a stress distribution interposer for mitigating substrate cracking.

### BACKGROUND

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches, which in and of themselves may also correspond to embodiments of the claimed subject matter.

When Ball Grid Array (BGA) components are mounted on a Printed Circuit Board (PCB), they experience stresses due to differences in the Coefficient of Thermal Expansion (CTE) property between the materials.

As the form factor requirements of electronics become thinner and thinner, so do the substrate materials including the Printed Circuit Board (PCB) upon which various electronic components are mounted and the stresses that such materials undergo becomes more problematic because the substrate materials become increasingly fragile as they become thinner and thinner. These stresses manifest in the form of substrate cracking, which in turn leads to trace cracking, which in turn disrupts the electrical signal and causes unit failure due to the cracked electrical traces on the substrates which can no longer carry electrical signals due to the cracking.

Issues surrounding substrate and subsequent trace cracking is especially problematic with the reliability of ultra thin (e.g., sub 1.5 mm thin) substrate packages which are in high demand today. The methodologies described herein improve the predictability of crack locations, reduce the appearance of crack initiation sites, and improve package thermal cycling endurance.

The present state of the art may therefore benefit from the stress distribution interposer for mitigating substrate cracking as is described herein.

### BRIEF DESCRIPTION OF THE DRAWINGS

Embodiments are illustrated by way of example, and not by way of limitation, and will be more fully understood with reference to the following detailed description when considered in connection with the figures in which:

FIG. 1 depicts a substrate package in accordance with described embodiments;

FIG. 2 depicts a representation of a Scanning electron microscope (SEM) image of a substrate package in accordance with described embodiments;

FIG. 3A depicts a package substrate in accordance with described embodiments;

FIG. 3B depicts another view of the package substrate in accordance with described embodiments;

FIG. 3C depicts another view of the package substrate in accordance with described embodiments;

FIG. 4A depicts another view of the package substrate having the interposer installed thereupon between the silicon die stack and the package substrate in accordance with described embodiments;

FIG. 4B depicts another view of the package substrate having a square edged interposer installed thereupon;

FIG. 4C depicts another view of the package substrate having an edge optimized interposer installed thereupon;

FIG. 5 depicts simulation results in accordance with the described embodiments;

FIG. 6 is a flow diagram illustrating a method for implementing a stress distribution interposer for mitigating substrate cracking in accordance with described embodiments; and

FIG. 7 is a schematic of a computer system, in accordance with described embodiments.

### DETAILED DESCRIPTION

Described herein are systems, apparatuses, and methods for implementing stress distribution interposers for mitigating substrate cracking. For instance, in accordance with one embodiment, there is an apparatus having therein: a substrate having electrical traces therein; a functional semiconductor die electrically interfaced to the electrical traces of the substrate; an interposer bonded at a bottom surface to the substrate and bonded at a top surface to the functional semiconductor die; and in which the interposer includes edges with a coefficient of thermal expansion and modulus which is between a coefficient of thermal expansion and modulus of the substrate and a coefficient of thermal expansion and modulus of the functional semiconductor die.

In the following description, numerous specific details are set forth such as examples of specific systems, languages, components, etc., in order to provide a thorough understanding of the various embodiments. It will be apparent, however, to one skilled in the art that these specific details need not be employed to practice the embodiments disclosed herein. In other instances, well known materials or methods have not been described in detail in order to avoid unnecessarily obscuring the disclosed embodiments.

In addition to various hardware components depicted in the figures and described herein, embodiments further include various operations which are described below. The operations described in accordance with such embodiments may be performed by hardware components or may be embodied in machine-executable instructions, which may be used to cause a general-purpose or special-purpose processor programmed with the instructions to perform the operations. Alternatively, the operations may be performed by a combination of hardware and software.

Any of the disclosed embodiments may be used alone or together with one another in any combination. Although various embodiments may have been partially motivated by deficiencies with conventional techniques and approaches, some of which are described or alluded to within the specification, the embodiments need not necessarily address or solve any of these deficiencies, but rather, may address only some of the deficiencies, address none of the deficiencies, or be directed toward different deficiencies and problems which are not directly discussed.

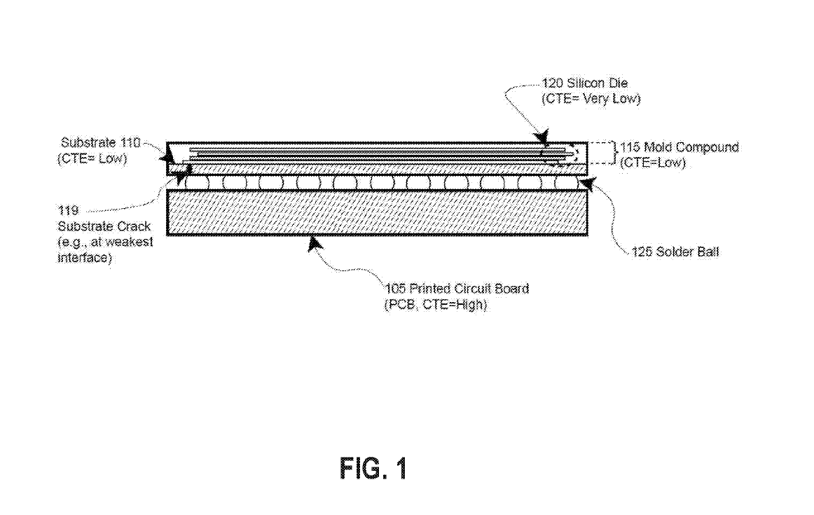

FIG. 1 depicts a substrate package in accordance with described embodiments. In particular, there is depicted a substrate 110 and a mold compound 115 both having a low Coefficient of Thermal Expansion (CTE) and a silicon die 120 having a very low CTE. The substrate 110 and mold compound 115 are positioned atop solder balls 125 which connect them to the underlying printed circuit board (PCB) 105 which in turn has a relatively high CTE. As depicted, a substrate crack 119 has developed at the weakest interface of the package which may lead to the aforementioned problems including a loss of trace connectivity and a failure of the package.

The resulting substrate crack 119 has formed in a typical area for the substrate package having the exemplary CTE values (e.g., high, low, very low) for the depicted package. The large differences in the Coefficient of Thermal Expansion (CTE) values between the PCB 105 and silicon die 120 results in the cracking as depicted.

Cracks most often occur at the colder extreme of the temperature variations for the package substrate in which the thermal expansion and contraction of the materials causes the motherboard PCB to retract and pull inwards on the solder balls which creates a pulling force on the package substrate. Because the package substrate expands and contracts to a lesser degree, it doesn't retract sufficiently at the cold temperatures and cracking forms at the edges in the substrate of these solder balls.

Within a computing device or a computing system there are various components which provide a wide array of functionality, all of which are ultimately connected together via a main system board such as a “motherboard” which is typically made out of glass and resin composites. The motherboard is usually thicker and sturdier in comparison to the materials of the various components that will be affixed to the mother board to provide the system with functionality.

Components have their own substrate or printed circuit board substrate interfaced to an outer board for the component. The substrate also has etched copper traces and will typically have a very thin layer of glass resin composites. The substrate of such a component is, however, typically much thinner and more fragile in comparison to a motherboard.

For instance, such a substrate may constitute any one of a ball grid array (BGA); an organic substrate (e.g., such as a resin based organic substrate); a Land Grid Array (LGA) substrate without sufficient solder to form the solder ball; or a Printed Circuit Board (PCB) thinner than 1.5 millimeters.

The purpose of the substrate of the component is to fan out the electrical signals of the silicon dies or other semiconductor elements mounted to the substrate. Any functionality needed by that component is ultimately housed within some silicon die or semiconductor affixed to the substrate making up the component's substrate package.

The various silicon dies and semiconductor elements are each smaller than the substrate and are built up to form the die stack package which is bonded to the substrate. The substrate is in turn then bonded to the outer board via solder balls.

Problematically, each of the differing elements making up a component's substrate package (e.g., the dies, the substrate, any ball grid array, solder balls, etc.,) each exhibit differing Coefficient of Thermal Expansion (CTE) values and during temperature cycling, either in lab testing or in situ when temperatures increase and decrease, the various elements of the substrate package expand and contract to differing amounts due to their differing CTE properties.

Each element expands and contracts according to its own material properties and the present operating condition of that component. Operating temperatures are not stable due to a variety of factors, such as environmental conditions, battery charge and discharge, system state being powered off, powered on at low computational load, powered on and at high computational load, etc. It is therefore realistic for any given computing device to undergo a widely varying range of operating temperatures and temperature cycling during normal operational use.

This repeated temperature cycling is especially problematic as it induces the changes in the thermal expansion and contraction repeatedly which weakens the component and ultimately leads to cracking and fracturing which severs or disrupts electrical traces and thus renders the component inoperable.

The silicon dies 120 tend to have the very lowest CTE and thus, the silicon dies 120 expand and contract the least. Conversely, the motherboard has the most resin and therefore has the greatest CTE and expands and contracts the most due to changing temperatures which then exhibit forces onto the solder balls connecting the motherboard with the component and those forces are then transmitted into the substrate crack 119 as stress concentrations. The substrate 110 is essentially glued to the silicon die 120 above and because of the mismatch between the thermal expansion of the materials of the substrate 110 and the silicon die 120 the depicted substrate cracks 119 may occur. Such cracks tend to develop around the edges of the silicon die 120 in what is known as the edge effect. Because the substrate is in contact with and is held firmly in place by the very hard crystal die material above it, the stresses build and tend to concentrate around the edges of the silicon die 120 resulting in cracks to the substrate 110 and severed electrical traces traversing the dielectric materials.

Spreading or distributing the otherwise concentrated stresses, especially at the edges of the silicon die 120, allows for a smoother transition of stresses, reducing the stress concentrations, and thus mitigating the potential for stress fractures and cracking in the substrate 110.

For a crack to develop a certain amount of stress must first occur and the stress concentration corresponds to a localized discontinuity of stress which causes the localized stress levels to exceed the threshold at which a stress crack will occur. The identical amount of stress, if spread out over a larger area such that it is no loner localized, will prevent any localized region from exceeding the same threshold, and thus, cracks will not develop in the substrate 110 for the same amount of stress.

In accordance with one embodiment, the package substrate, the interposer, and the functional semiconductor dies are backfilled or over molded with a mold compound 115 to form a package. According to such an embodiment, the mold compound 115 is of a lower coefficient of thermal expansion in than the interposer but of a greater coefficient of thermal expansion than the functional semiconductor die. According to one embodiment the mold compound is of a lower modulus (e.g., less hard and more flexible) than the interposer as it is formed from a mix of ceramic materials and resin.

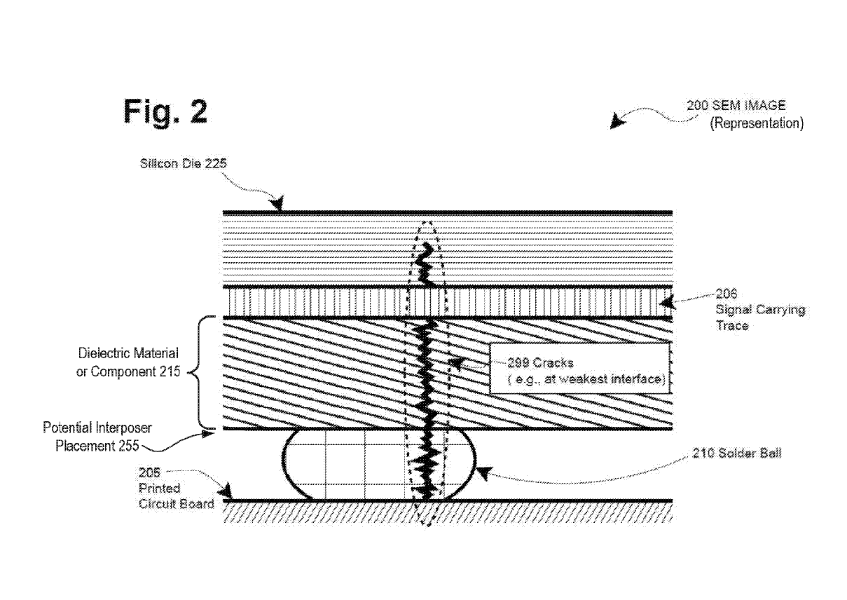

FIG. 2 depicts a representation of a Scanning electron microscope (SEM) image 200 of a substrate package in accordance with described embodiments. In particular, there are depicted the silicon die 225 having therein a signal carrying trace 206 through dielectric 215 material through which cracks 299 have developed at the weakest interface. Further depicted is a solder ball 210 connecting the silicon die 225 package to the printed circuit board 205 below.

As depicted by the representation of the SEM image 200, the crack 299 travels up near the side of the solderball and through the signal carrying trace. The major stress concentrations on the package for the silicon die 225 reside at the silicon die 225 edge and at the solderball connection 210 between the dielectric material 215 and the printed circuit board 205.

In accordance with described embodiments, a potential interposer placement 255 is between the first functional semiconductor die and the printed circuit board 205 substrate to more smoothly transition the large differences in the Coefficient of Thermal Expansion (CTE) values of the various materials from the abrupt transition attributable to the differing material property CTEs to a gradual transition through such an interposer.

According to a particular embodiment, an optimal and relatively non-intrusive silicon interposer with an irregular edge is added at the potential interposer placement position 255 as depicted.

According to such an embodiment, a silicon interposer having an irregular edge introduces an area with transitional material properties, such as a Coefficient of Thermal Expansion which is greater than the very low CTE of the silicon die 225 but less than the relatively high CTE of the printed circuit board 205 or other substrate.

In such a way, the stresses arising from the Coefficient of Thermal Expansion (CTE) mismatch are redistributed over a much larger area via the larger surface area of the interposer which reduces the maximum stress in any given area and therefore permits increased substrate reliability and life span.

Prior solutions have restricted the permissible substrates, dielectric materials, components, and silicon dies to materials having similar Coefficient of Thermal Expansion values so as to minimize the CTE mismatch in an effort to obviate the potential for cracking and package failure. While such a solution is feasible, it does introduce engineering complexity, increases the cost of materials, restricts the availability of what materials and components may be utilized, and generally increases the total cost of production for the resulting package, especially in terms of increased materials costs on a per unit basis.

Moreover, such an approach may nevertheless remain inadequate for use cases where the printed circuit board is a customer design and cannot therefore be controlled within the package manufacturing process.

Engineering a specific substrate design is also feasible which seeks to introduce design optimizations for the substrate by, for example, increasing copper width and thickness. Unfortunately, this approach is known to reduce the potential signal density and conflicts with other substrate design considerations. Moreover, engineering substrate design optimization additionally requires knowledge of the eventual stress concentration locations which can be complex and unpredictable. This is because stress concentrations can shift depending on the localized material properties.

Conversely, use of an interposer may be applied across all known customer use cases within only incremental cost increases for the resulting package and does not require PCB 205 and motherboard changes to existing designs. Further still, substrate signal density is maintained through preferred trace thickness and width design and when cracks do occur, the crack locations are more predictable with the use of an interposer and can therefore be more readily accommodated at design time.

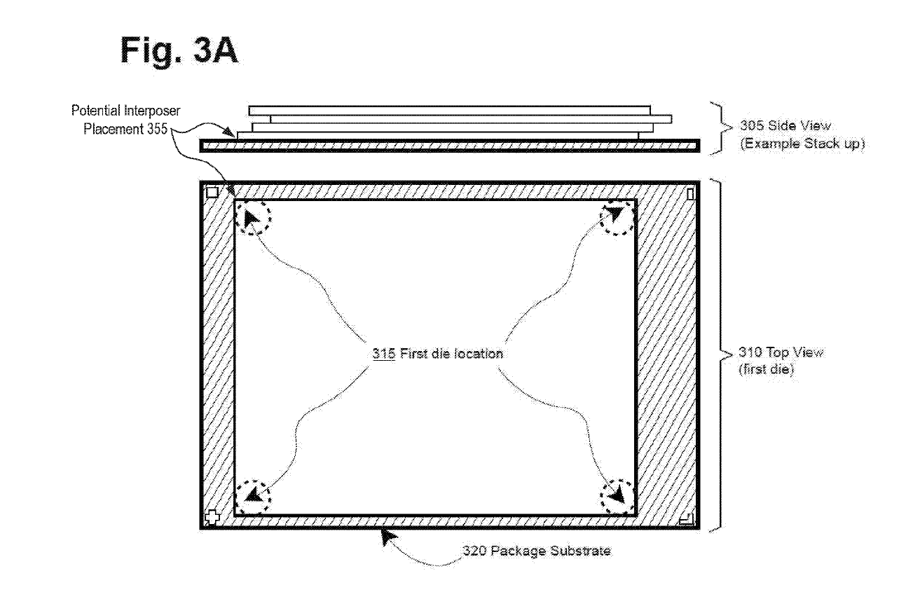

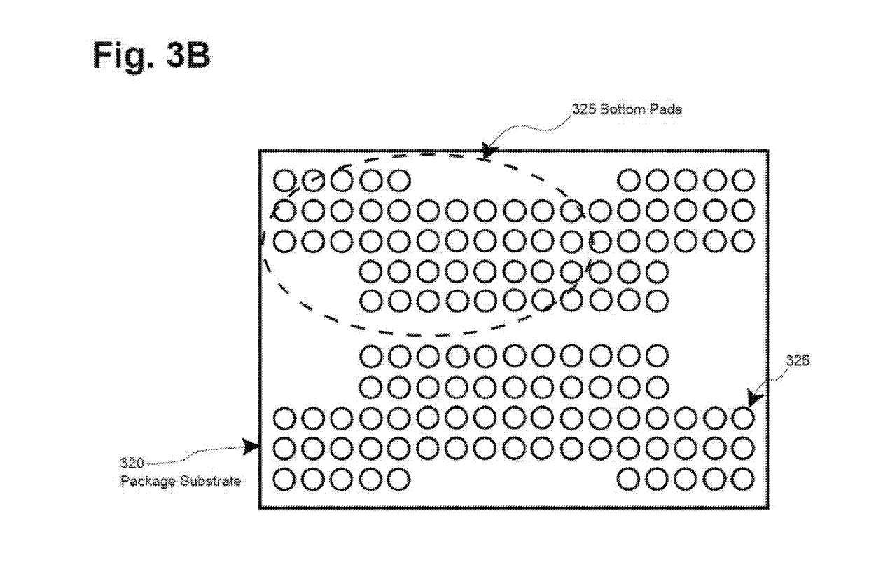

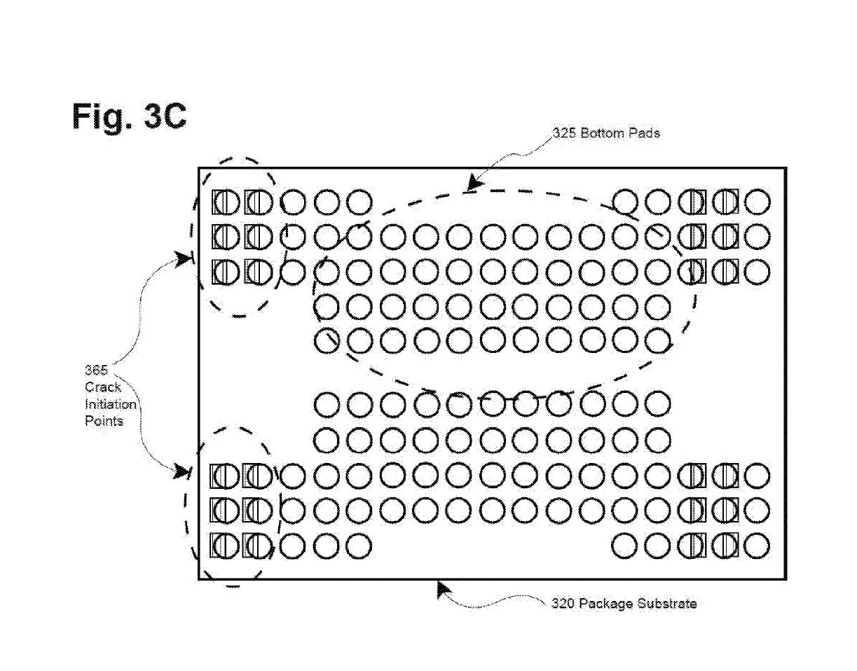

FIG. 3A depicts a package substrate 320 in accordance with described embodiments. In particular, there is both a top view 310 of the first die and a side view 305 showing the stack up of the package substrate and the silicon dies mounted thereupon in a 2×2 zigzag formation.

According to a particular embodiment, the package substrate 320 forms a 3D semiconductor package or a 3D package substrate in which the 3D packaging is achieved with the use of through-mold first level interconnects (FLI) via an FLI layer above the substrate 130. According to one embodiment, the interposer embodies the FLI layer. Such 3D packaging embodiments may include, for example, 3D stacked die, face-to-face 3D stacking, through-mold FLI, and 3D stacked die on a central processing unit (CPU). In certain embodiments, two or more die are stacked without the use of through silicon vias (TSVs) or wire-bonds in which a TSV approach is a through approach, whereas a wirebond approach is a bypass approach. One or more embodiments described herein may be characterized as a hybrid through and by-pass approach. In an embodiment, one or more smaller dies are packaged face-to-face with a larger die.

Stresses in the package substrate 320 concentrate around the edges of the first die location 316 as depicted by the inset dashed circles at the corners of the die stack viewable from the top view 310 representation.

Potential interposer placement 355 depicts the potential location of the proposed interposer between the package substrate 320 and the first functional die placed upon the substrate.

In accordance with one embodiment the first functional semiconductor die is wire bonded to the substrate, in which the wire bonds traverse the edge of the interposer to the substrate below the interposer when the interposer is positioned in between the first functional semiconductor die and the substrate.

In accordance with one embodiment the functional semiconductor dies are offset or stacked in a zigzag formation (e.g., a 2×2 zigzag formation) so as to provide space for the wire bonded interfaces at the edges of each of the respective functional semiconductor dies, in which the wire bonds traverse over the edge of the interposer and are electrically connected with the package substrate below the interposer.

FIG. 3B depicts another view of the package substrate 320 in accordance with described embodiments. In particular, there is depicted a Ball Grid Array (BGA) having multiple bottom pads 325 through which the higher level silicon die stack is electrically interfaced to the package substrate 320 via the individual solder balls making up the bottom pads 325 of the ball grid array.

Additional stresses tend to concentrate at the edge of the Ball Grid Array (BGA) pads. Cracking tends to initiate in areas where these stresses are concurrent with the corners of the first die placement.

FIG. 3C depicts another view of the package substrate 320 in accordance with described embodiments. In particular, there is depicted the Ball Grid Array (BGA) having thereupon multiple solder balls constituting the bottom pads 325. Additionally depicted here are the likely crack initiation points 365 which are encircled via the dashed lines on the upper left and lower left corners. Similar crack initiation points 365 are present on the upper right and lower right corners, but are not circled.

Comparing FIGS. 3A and 3C, it can be seen that the high stress areas at the corners of the first die location (element 315 from FIG. 3A) and the higher stress regions at the corners of the ball grid array (refer to the corners of FIG. 3C) are concurrent, and are therefore likely crack initiation points 365.

The edges of the first silicon die are a principle contributor to the development of stress concentrations and the profile of those stress concentrations. As highlighted by the crack initiation points 365, it is the edges in particular of the solder balls of the ball grid array which experience the highest stresses due to the solder balls being held fast to the motherboard PCB which expands and contracts to a greater degree than any of the other components. Because the edges of the silicon die are holding the package substrate 320 fixedly in place there develops two opposing forces and the stress concentration profile becomes highly concentrated in the areas identified at FIG. 3C as crack initiation points 365.

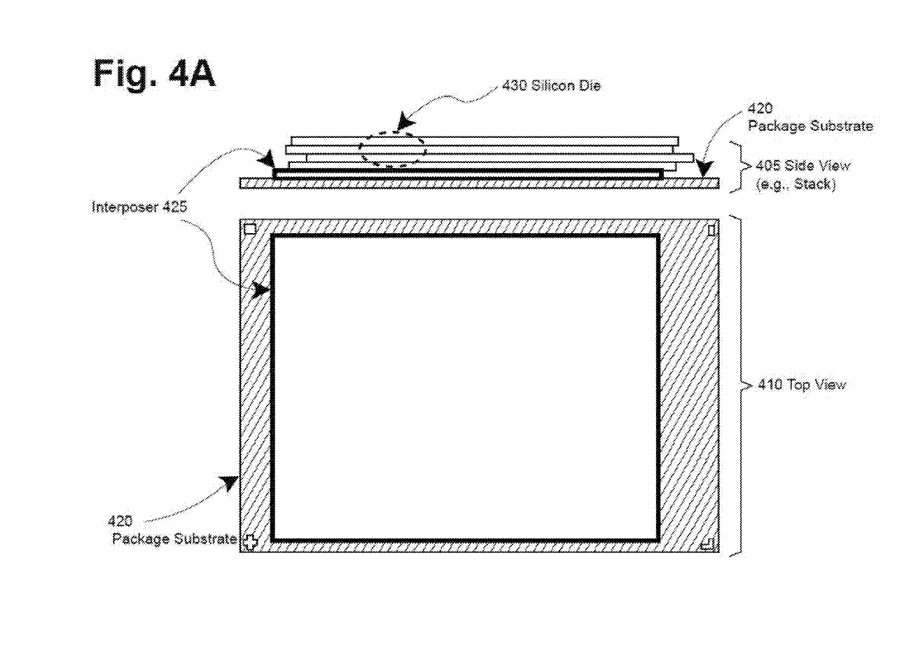

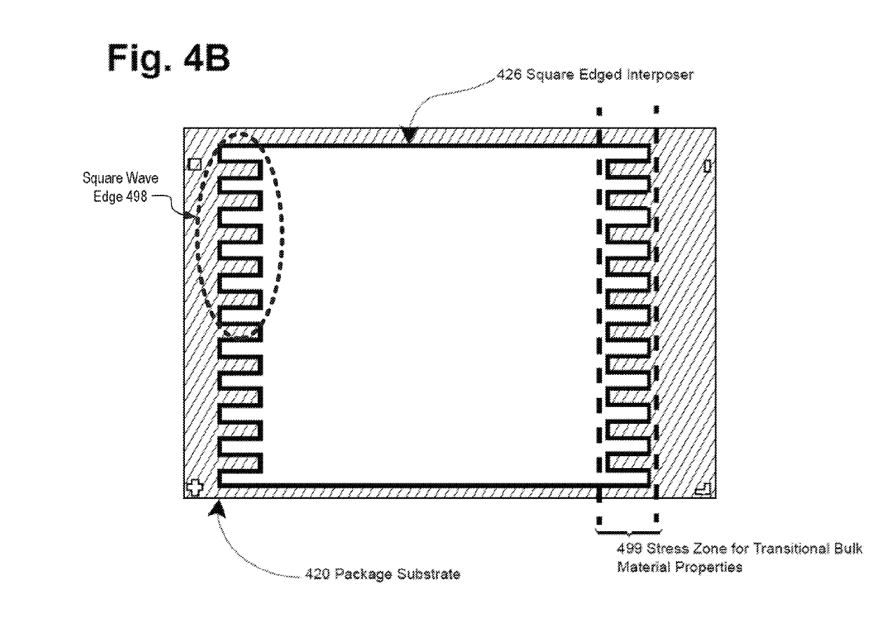

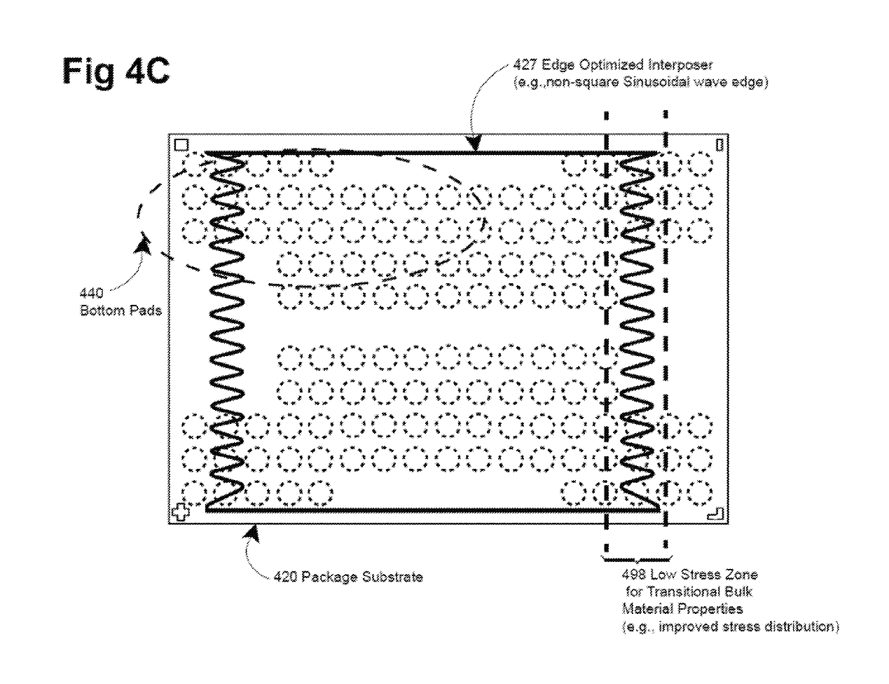

FIG. 4A depicts another view of the package substrate 420 having the interposer 425 installed thereupon between the silicon die 430 stack and the package substrate. Depicted are both a top view 410 showing the interposer 425 on top of the package substrate 420 beneath the silicon die 430 and also a side view 405 showing the stack up of the package substrate 420 and then the interposer 425 and finally the silicon die stack 430 in a 2×2 zigzag formation.

At FIG. 4A, likely crack initiation points are at the ball grid array edges near the die edges where the stresses of the ball grid array and the first functional die are concurrent. Having the interposer 425 placed beneath the first functional die, the interposer mitigates the high stress points and negates potential cracks and factures by providing an interface between the high CTE property materials such as the package substrate 420 and the low CTE property materials such as the silicon die 430. For instance, the interposer 425 as depicted may be comprised of a material with Coefficient of Thermal Expansion (CTE) properties and a stiffness which is transitional between the silicon die 430 and the package substrate 420. Stated differently the interposer provides a Coefficient of Thermal Expansion which is greater than the very low CTE of the silicon die 430 but less than the relatively high CTE of the package substrate 420, such as a printed circuit board or other high CTE substrate.

In such a way, the stresses arising from the Coefficient of Thermal Expansion (CTE) mismatch is redistributed over a much larger area via the larger surface area of the interposer which reduces the maximum stress in any given area and therefore permits increased reliability and life span of the entre package including the substrate, the silicon die stack and importantly the electrical traces.

Introduction of the interposer 425 material between the first silicon die 430 and the package substrate 420 provides a geometric zone of interposing material which results in a transitional zone having a mixed or a reduced amount of hardness and thermal expansion compared to the silicon die 430.

FIG. 4B depicts another view of the package substrate 420 having a square edged interposer 426 installed thereupon. Stress zones for transitional bulk material properties 499, such as those areas having poor stress distribution, are depicted at the right edge of the squared edged interposer 426 which provides for improved transition of stresses in the stress zone 499.

A material optimized interposer 425 such as that which is depicted at FIG. 4A provides a CTE transition in the Z dimension (e.g., normal to the surface of the substrate) and thus yields improved distribution and transition of stresses between the various layers of the substrate package in the stress zone 499. The square edged interposer 426 provides still further improvement through the depicted manipulation of the interposer's edge geometry so as to mechanically create CTE transitional zones in the X-Y dimensions (e.g., in-plane dimensions of the substrate) in addition to the improved CTE transition in the Z dimension.

The depicted square wave edge 498 of the square edged interposer 426 effectively exhibits bulk material properties halfway between the silicon die and the matrix of the substrate package, be it air, mold compound, or another material which would otherwise be in contact with the package substrate 420 outside the silicon die edge.

Rather than concentrations of hard or abrupt stresses at the edges of the silicon die as is the case with conventional solutions, the depicted square edged interposer 426 spreads both the Coefficient of Thermal Expansion (CTE) transition and also the modulus transition (e.g., hardness or elasticity of the material) over a larger area.

In accordance with one embodiment, the interposer 425 is manufactured with square or rectangular coupons at one or more edges, also referred to as the square edged interposer 426 which results in the edge of such an interposer having half open space and half silicon die. This mechanical or geometric shape results in a material property for the square edged interposer 426 which effectively averages out to half of the thermal expansion of the square edged interposer 426 at the edge if the empty space between the coupons were not present. With half the hardness of the material the stress concentration is spread out more evenly across this edge of the square edged interposer 426 at the region indicated by element 499 forming the stress zone for transitional bulk material properties effectively averaging the edge of square edged interposer 426 over region 499 rather than a straight edge to the corner.

In accordance with one embodiment the interposer is a non-functional semiconductor die having a geometric shaped edge which is an average of the material properties, at the edge region, of the silicon material of the first functional semiconductor die and the mold compound (or the lack of a mold compound as is the case with certain packages) surrounding the silicon die stack.

According to a particular embodiment, the interposer is formed from a mold compound having a low coefficient of thermal expansion and a high modulus having material properties which are an average of the package substrate and the functional semiconductor die in terms of thermal expansion and modulus.

In accordance with such an embodiment, the thermal expansion and modulus properties of the material from which the interposer is manufactured is equal to or closer to the thermal expansion and modulus properties of the first silicon die and the cutouts, coupons, tabs or geometric shaped edge of the interposer changes the thermal expansion and modulus properties of the interposer at an edge region subjected to the changed geometric shape.

According to one embodiment, the voids or spaces formed from the cutouts, coupons, tabs or geometric shaped edge of the interposer are back filled with a mold compound which encapsulates the resulting package of the substrate, the interposer, and the functional semiconductor dies.

FIG. 4C depicts another view of the package substrate 420 having an edge optimized interposer 427 installed thereupon. In particular, the edge optimized interposer 427 depicted here provides a non-square sinusoidal wave edge to provide a low stress zone 498 for transitional bulk material properties resulting in improved stress distribution. As depicted, the edge optimized interposer 427 is mounted upon the package substrate 420 over the bottom pads 440 formed by the ball grid array's solder balls which electrically interface to the first functional semiconductor die of the die stack.

In accordance with described embodiments, the shape of the edge optimized interposer 427 may be modified and manipulated to mechanically induce varying CTE and modulus characteristics appropriate for smoothing or better distributing otherwise abrupt material transitions between the package substrate 420 and the silicon die or other mismatched CTE materials susceptible to cracking, fracture, or other failure modes attributable to high stress regions within the package.

In particular, the edge optimized interposer 427 need not exhibit square wave or Sinusoidal wave edges as depicted here, but rather, may take on any shape appropriate for the package and remain consistent with the described embodiments. Any shape of the edge optimized interposer 427 which avoids compounding the stresses to the first functional semiconductor die of a die stack or other stress concentrations otherwise present in the package substrate such as stresses at the solderball pad edges may be utilized to reduce stress concentrations and negate potential cracks and fractures through improved stress distribution and improved CTE material transitions through the edge optimized interposer 427.

In accordance with a particular embodiment, the stress concentrations at the higher risk regions of the ball grid array are negated or sufficiently reduced by the shape of the edge optimized interposer 427 as depicted at FIG. 4C such that the regions with the greatest stress concentration benefit most from the Sinusoidal wave edge placement in which the transitional CTE and modulus characteristics of the edge optimized interposer 427 are purposefully aligned. For instance, the high risk ball placements of the bottom pads represented by the dotted circles within the ball grid array are centered in the troughs of the wave pattern of the edge optimized interposer 427.

An interposer having a straight edge provides a benefit in of itself by establishing an intervening material with transitional CTE and modulus between the surrounding layers, such as the first silicon die of a die stack and the package substrate and its ball grid array, however, the edge optimized interposer 427, be it a square wave, a sinusoidal wave, or some other shape, provides still further benefits as specifically pinpointed high stress concentrations may be alleviated through the shape of the interposer edge, such as placing such areas within a wave trough, etc.

Similar to the coupons forming the edge of the square edged interposer 426 at FIG. 4B, such coupons or tabs may similarly be formed from the sinusoidal wave pattern as depicted at FIG. 4C. Such a wave pattern need not be sinusoidal and need not exhibit equal peaks and troughs. Moreover, because the patterns may be optimized to avoid the edges of the solder balls where the greatest stress concentrations tend to develop the shape of the edge or the wave pattern may be geometrically manipulated such that areas with known stress concentrations, such as the solder ball edges, are paired with a low amount of the interposer's silicon material above them whereas other areas which exhibit lesser stress concentrations may have greater amounts of the interposer's silicon above them so as to attract additional stresses with the aim of providing better stress distribution for the package substrate 420 as a whole.

In accordance with described embodiments, a first surface of the interposer is bonded to the substrate and the silicon die is bonded onto a second surface of the interposer. According to such an embodiment, the interposer is bonded to either or both of the silicon die and the package substrate via die attached film or die attached paste.

In accordance with one embodiment the interposer has edges with thermal expansion and modulus properties which are an average of the thermal expansion and modulus properties of a first material above the interposer and the thermal expansion and modulus properties of a second material below the interposer. For instance, the interposer may exhibit thermal expansion and modulus properties which correspond to an average of the thermal expansion and modulus properties of a silicon die above the interposer and the thermal expansion and modulus properties of the package substrate below the interposer. In an alternative embodiment, the thermal expansion and modulus properties of the interposer are an average of the thermal expansion and modulus properties of the silicon die above and the thermal expansion and modulus properties of a motherboard PCB upon which the package substrate is soldered or upon which the package substrate is to be soldered after manufacture. According to another embodiment, the thermal expansion and modulus properties of the interposer are between those of a first material above and a second material below, such as between the CTE and modulus of a silicon die above and the CTE and modulus of a package substrate or motherboard PCB below. The modulus of the interposer, the silicon die, the package substrate, or the motherboard PCB may alternatively be referred to as the hardness or elasticity of those materials.

According to another embodiment, changes to the thermal expansion and modulus properties of the interposer are attained through geometric manipulation of the edges of the interposer. According to an alternative embodiment, changes to the thermal expansion and modulus properties of the interposer are attained through modification to the materials or material compounds from which the interposer is manufactured. According to another embodiment, changes to the thermal expansion and modulus properties of the interposer are attained through modification to the shape of the interposer.

Although we refer to the interposer herein as being a potentially non-functional silicon material having transitional thermal expansion and modulus properties between the first functional die and the underlying package substrate, embodiments include utilizing the first functional die as an interposer and functional die combination in which changes to the thermal expansion and modulus properties of the interposer and functional die combination are attained through geometric manipulation of the edges of the interposer and functional die combination. Stated differently, the first functional die of the die stack (e.g., the bottom most functional die) may be manufactured with edges that geometrically average out the thermal expansion and modulus properties of the material from which the interposer and functional die combination are manufactured. In such a way, the edges of the silicon die would take on the square wave edge shape or the sinusoidal wave edge shape or another desired shape to attain the desired thermal expansion and modulus properties of such an interposer and functional die combination.

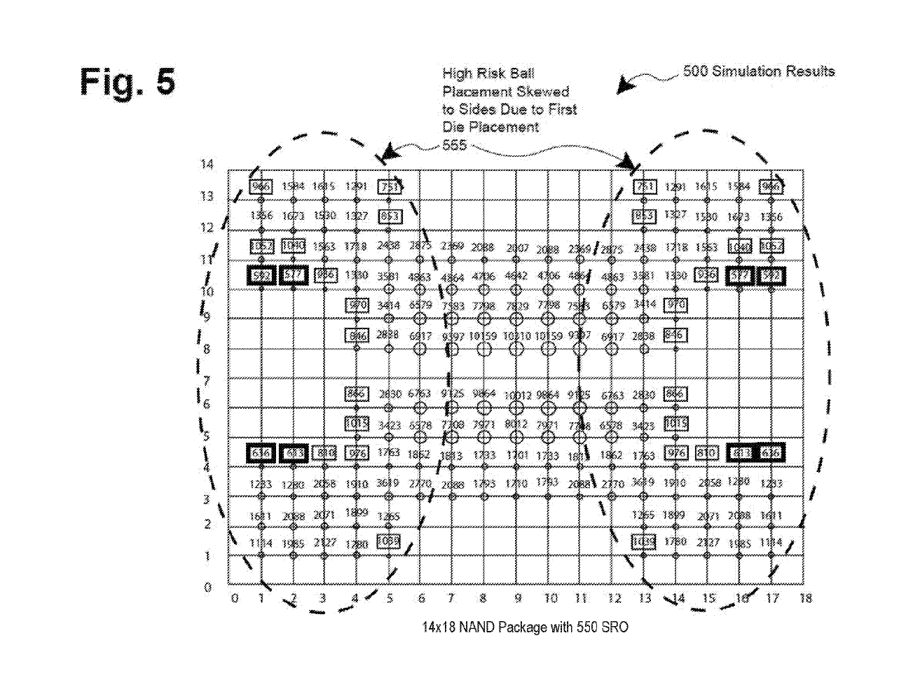

FIG. 5 depicts simulation results 500 in accordance with the described embodiments. In particular, the simulation results 500 represent high risk ball placement which is skewed to the sides (laterally left and laterally right) due to the first die placement as depicted at element 555. More specifically, the results indicate that the higher stress concentrations are present toward the edges of the ball grid array according to the simulation results in which the thick bold lines represent the highest risk areas, the outlined regions representing areas of medium risk ball placement, and the non-outlined areas representing low risk ball placement. Notably, the highest risk regions tend to skew toward the edges due to the concurrence of ball grid array edges and also the edges or corners of the first silicon die placement upon the package substrate via the solder balls of the ball grid array.

The simulation results 500 were generated with composite material properties having an average of the individual material constituents in the build materials which is a generally accepted approximation for the properties of thermal expansion and modulus of elasticity. Temperature life cycling on the ball grid of a 3rd party package was performed which rendered the high risk and medium risk ball placements including the depicted skew to the sides of the ball grid array due to the first die placement which was located toward the upperside of the depicted grid.

From the high stress regions it may be inferred that an excessively high amount of stress is being transferred to the substrate from the high stress regions of the ball grid array.

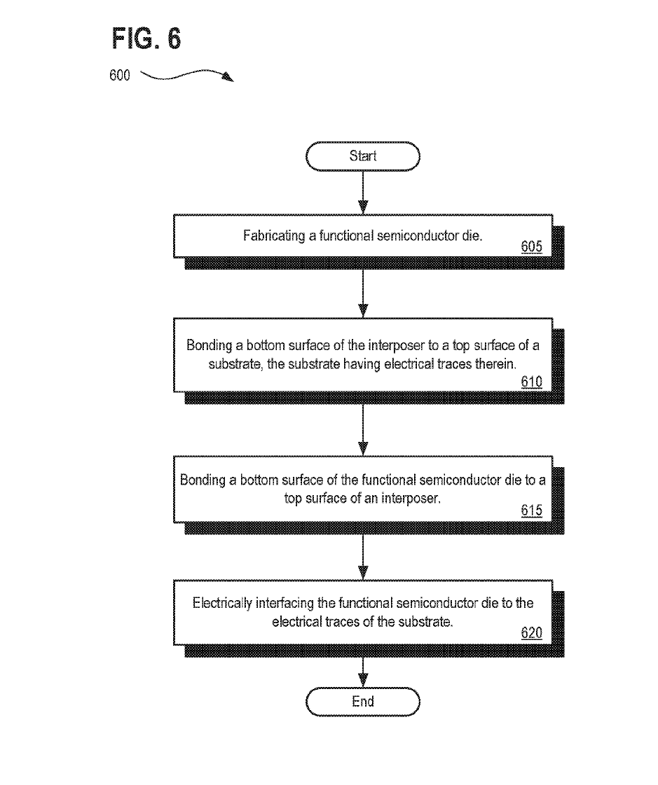

FIG. 6 is a flow diagram illustrating a method 600 for implementing a stress distribution interposer for mitigating substrate cracking in accordance with described embodiments. Some of the blocks and/or operations listed below are optional in accordance with certain embodiments. The numbering of the blocks presented is for the sake of clarity and is not intended to prescribe an order of operations in which the various blocks must occur. Additionally, operations from flow 600 may be utilized in a variety of combinations.

At block 605 the method includes fabricating a functional semiconductor die.

At block 610 the method includes bonding a bottom surface of the interposer to a top surface of a substrate, the substrate having electrical traces therein.

At block 615 the method includes bonding a bottom surface of the functional semiconductor die to a top surface of an interposer.

At block 620 the method includes electrically interfacing the functional semiconductor die to the electrical traces of the substrate.

In accordance with such an embodiment of method 600, the interposer includes edges with a coefficient of thermal expansion and modulus which is between a coefficient of thermal expansion and modulus of the substrate and a coefficient of thermal expansion and modulus of the functional semiconductor die.

In accordance with another embodiment of method 600, the interposer having the edges with the coefficient of thermal expansion and modulus between that of the substrate the functional semiconductor die is further characterized such that: the edges of the interposer have an average coefficient of thermal expansion and modulus equivalent to (i) the coefficient of thermal expansion and modulus of the substrate and (ii) the coefficient of thermal expansion and modulus of the functional semiconductor die.

In accordance with another embodiment of method 600, the edges of the interposer include one or more non-linear irregular edges with transitional material properties including at least the coefficient of thermal expansion greater than the coefficient of thermal expansion of the functional semiconductor die and lesser than the coefficient of thermal expansion of the substrate.

In accordance with another embodiment of method 600, the edges of the interposer reduce stress concentrations of the substrate to mitigate cracking of the substrate by distributing stresses over a greater surface area via the interposer.

In accordance with another embodiment of method 600, one or more of the edges of the interposer form a square wave edge of the interposer having material properties between the coefficient of thermal expansion and modulus of the substrate and the coefficient of thermal expansion and modulus of the functional semiconductor die.

In accordance with another embodiment of method 600, one or more of the edges of the interposer form a non-square sinusoidal wave edge of the interposer to provide a low stress zone for transitional bulk material properties to increase stress distribution of the substrate.

In accordance with another embodiment of method 600, the interposer has one or more non-linear edges forming spaces in the one or more non-linear edges of the interposer and further in which one or more of the spaces are positioned above a corresponding one or more solder balls affixed to the substrate.

In accordance with another embodiment of method 600, the interposer forms a second functional semiconductor die electrically interfaced to the electrical traces of the substrate; and in which the interposer which forms the second functional semiconductor die has one or more non-linear edges having one of: a square wave edge, a sinusoidal wave edge, or a non-linear and irregular shaped edge.

In accordance with another embodiment of method 600, the substrate includes one of: a ball grid array (BGA); an organic substrate; a Land Grid Array (LGA) substrate; and a Printed Circuit Board (PCB) less than 1.5 millimeters thin.

In accordance with another embodiment of method 600, the apparatus embodies a component package including at least the substrate, the interposer, and the functional semiconductor die.

In accordance with another embodiment of method 600, the component package is backfilled or over-molded with a mold compound.

In accordance with another embodiment of method 600, the mold compound exhibits a lower coefficient of thermal expansion than the interposer and a greater coefficient of thermal expansion than the functional semiconductor die; and in which the mold compound is of a lower modulus than the interposer.

In accordance with another embodiment of method 600, the interposer has one or more non-linear edges forming spaces in the one or more non-linear edges of the interposer and further in which the mold compound partially encapsulates the component package of the substrate, the interposer, and the functional semiconductor die including backfilling with the mold compound the spaces formed in the one or more non-linear edges of the interposer.

In accordance with another embodiment of method 600, the component package further includes a functional die stack including at least the functional semiconductor die as a first functional semiconductor die positioned at the bottom most layer of the functional die stack and one or more additional functional semiconductor dies positioned above and bonded to the first functional semiconductor die.

In accordance with another embodiment of method 600, the component package includes the functional semiconductor die and one or more additional functional semiconductor dies as a functional semiconductor die stack; and in which each of the functional semiconductor dies are wire bonded to the electrical traces of the substrate.

For instance, the a first functional semiconductor die in a top most position may be a memory silicon die and a second functional semiconductor die in the first or bottom position may be a logic silicon die or a System on a Chip (SoC) functional semiconductor die or both functional semiconductor dies may be memories, and so forth.

In accordance with another embodiment of method 600, the substrate is electrically interfaced to a motherboard PCB via solder balls of a ball grid array or alternatively in which the substrate is to be electrically interfaced to a motherboard PCB via solder balls of a ball grid array by a third party other than the manufacturer of the apparatus; and in which the motherboard PCB has a coefficient of thermal expansion greater than any of the substrate, the interposer, and the functional semiconductor die.

In accordance with another embodiment of method 600, both the functional semiconductor die and the interposer are formed from any of Silicon dioxide (SiO2), GaAs, alumina, sapphire, germanium, etc. According to such embodiments, the interposer formed from SiO2, GaAs, alumina, sapphire, or germanium exhibits a coefficient of thermal expansion different than the functional semiconductor die formed from SiO2, GaAs, alumina, sapphire, or germanium, due to one or more geometrically manipulated and non-linear edges of the interposer.

According to a related embodiment, there is an apparatus which includes: a substrate having electrical traces therein; a functional semiconductor die electrically interfaced to the electrical traces of the substrate; an interposer bonded at a bottom surface to the substrate and bonded at a top surface to the functional semiconductor die; in which the interposer includes edges with a coefficient of thermal expansion and modulus which is between a coefficient of thermal expansion and modulus of the substrate and a coefficient of thermal expansion and modulus of the functional semiconductor die.

According to another related embodiment, there is a system which includes: a processor and a memory to execute instructions; a printed circuit board (PCB) motherboard having the processor and the memory mounted thereupon; and a component package mounted to the PCB motherboard, in which the component package includes at least: (i) a substrate having electrical traces therein, (ii) a functional semiconductor die electrically interfaced to the electrical traces of the substrate, (iii) an interposer bonded at a bottom surface to the substrate and bonded at a top surface to the functional semiconductor die, and wherein the interposer comprises edges with a coefficient of thermal expansion and modulus which is between a coefficient of thermal expansion and modulus of the substrate and a coefficient of thermal expansion and modulus of the functional semiconductor die.

According to another related embodiment, the substrate of the component package in such a system includes one of: a ball grid array (BGA); an organic substrate; a Land Grid Array (LGA) substrate; or a Printed Circuit Board (PCB) less than 1.5 millimeters thin; and in which the component package is mounted to the PCB motherboard via solder balls of the substrate.

According to another related embodiment, the system is embodied within one of: a smart phone; a tablet; a hand-held computing device; a personal computer; or a wearable technology to be worn as a clothing item or an accessory.

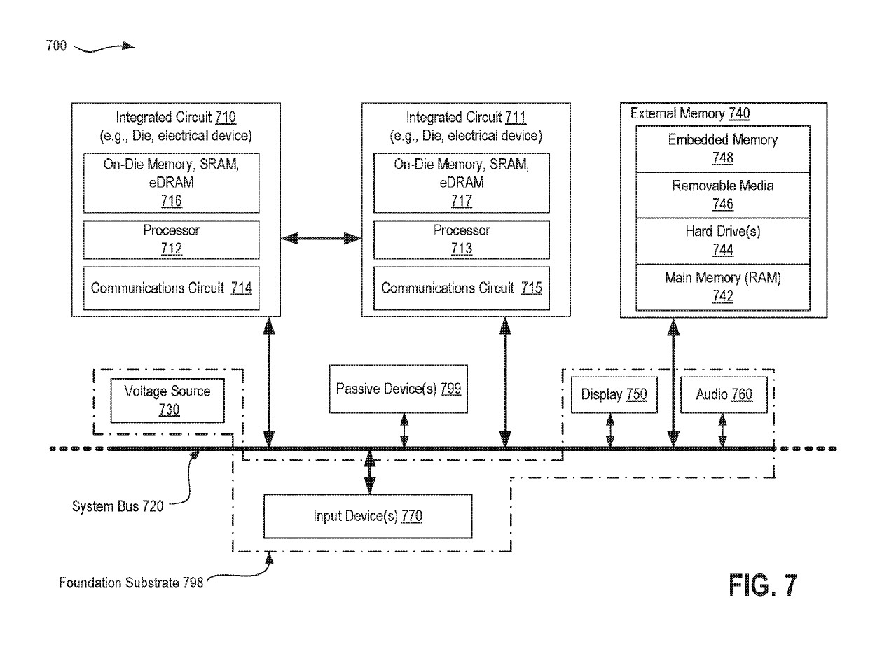

FIG. 7 is a schematic of a computer system 700, in accordance with described embodiments. The computer system 700 (also referred to as the electronic system 700) as depicted can embody a stress distribution interposer for mitigating substrate cracking, according to any of the several disclosed embodiments and their equivalents as set forth in this disclosure. The computer system 700 may be a mobile device such as a net-book computer. The computer system 700 may be a mobile device such as a wireless smart phone or tablet. The computer system 700 may be a desktop computer. The computer system 700 may be a hand-held reader. The computer system 700 may be a server system. The computer system 700 may be a supercomputer or high-performance computing system.

In accordance with one embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

Such an integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, electrical devices having a stress distribution interposer for mitigating substrate cracking, as disclosed herein.

In accordance with one embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In accordance with one embodiment, the integrated circuit 710 is complemented with a subsequent integrated circuit 711. Useful embodiments include a dual processor 713 and a dual communications circuit 715 and dual on-die memory 717 such as SRAM. In accordance with one embodiment, the dual integrated circuit 710 includes embedded on-die memory 717 such as eDRAM.

In one embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In accordance with one embodiment, the electronic system 700 also includes a display device 750 and an audio output 760. In one embodiment, the electronic system 700 includes an input device 770 such as a controller that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having a stress distribution interposer for mitigating substrate cracking, according to any of the several disclosed embodiments and their equivalents, an electronic system, a computer system, one or more methods of fabricating an integrated circuit, and one or more methods of fabricating an electronic assembly that includes a package substrate having a stress distribution interposer for mitigating substrate cracking, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a stress distribution interposer for mitigating substrate cracking embodiments and their equivalents. A foundation substrate 798 may be included, as represented by the dashed line of FIG. 7. Passive devices 799 may also be included, as is also depicted in FIG. 7.

While the subject matter disclosed herein has been described by way of example and in terms of the specific embodiments, it is to be understood that the claimed embodiments are not limited to the explicitly enumerated embodiments disclosed. To the contrary, the disclosure is intended to cover various modifications and similar arrangements as would be apparent to those skilled in the art. Therefore, the scope of the appended claims should be accorded the broadest interpretation so as to encompass all such modifications and similar arrangements. It is to be understood that the above description is intended to be illustrative, and not restrictive. Many other embodiments will be apparent to those of skill in the art upon reading and understanding the above description. The scope of the disclosed subject matter is therefore to be determined in reference to the appended claims, along with the full scope of equivalents to which such claims are entitled.

It is therefore in accordance with the described embodiments that:

According to one embodiment there is an apparatus to mitigate substrate cracking, the apparatus comprising: a substrate having electrical traces therein; a functional semiconductor die electrically interfaced to the electrical traces of the substrate; an interposer bonded at a bottom surface to the substrate and bonded at a top surface to the functional semiconductor die; and wherein the interposer comprises edges with a coefficient of thermal expansion and modulus which is between a coefficient of thermal expansion and modulus of the substrate and a coefficient of thermal expansion and modulus of the functional semiconductor die.

According to one embodiment, the interposer having edges with the coefficient of thermal expansion and modulus which is between that of the substrate the functional semiconductor die comprises: the edges of the interposer having an average coefficient of thermal expansion and modulus equivalent to (i) the coefficient of thermal expansion and modulus of the substrate and (ii) the coefficient of thermal expansion and modulus of the functional semiconductor die.

According to one embodiment, the edges of the interposer comprise one or more non-linear irregular edges with transitional material properties including at least the coefficient of thermal expansion greater than the coefficient of thermal expansion of the functional semiconductor die and lesser than the coefficient of thermal expansion of the substrate.

According to one embodiment, the edges of the interposer reduce stress concentrations of the substrate to mitigate cracking of the substrate by distributing stresses over a greater surface area via the interposer.

According to one embodiment, one or more of the edges of the interposer form a square wave edge of the interposer having material properties between the coefficient of thermal expansion and modulus of the substrate and the coefficient of thermal expansion and modulus of the functional semiconductor die.

According to one embodiment, one or more of the edges of the interposer form a non-square sinusoidal wave edge of the interposer to provide a low stress zone for transitional bulk material properties to increase stress distribution of the substrate.

According to one embodiment, the interposer has one or more non-linear edges forming spaces in the one or more non-linear edges of the interposer and further wherein one or more of the spaces are positioned above a corresponding one or more solder balls affixed to the substrate.

According to one embodiment, the interposer forms a second functional semiconductor die electrically interfaced to the electrical traces of the substrate; and wherein the interposer which forms the second functional semiconductor die has one or more non-linear edges having one of: a square wave edge, a sinusoidal wave edge, or a non-linear and irregular shaped edge.

According to one embodiment, the substrate comprises one of: a ball grid array (BGA); an organic substrate; a Land Grid Array (LGA) substrate; and a Printed Circuit Board (PCB) less than 1.5 millimeters thin.

According to one embodiment, the apparatus embodies a component package comprised of at least the substrate, the interposer, and the functional semiconductor die.

According to one embodiment, the component package is backfilled or over-molded with a mold compound.

According to one embodiment, the mold compound exhibits a lower coefficient of thermal expansion than the interposer and a greater coefficient of thermal expansion than the functional semiconductor die; and wherein the mold compound is of a lower modulus than the interposer.

According to one embodiment, the interposer has one or more non-linear edges forming spaces formed in the one or more non-linear edges of the interposer and further wherein the mold compound partially encapsulates the component package of the substrate, the interposer, and the functional semiconductor die including backfilling with the mold compound the spaces the one or more non-linear edges of the interposer.

According to one embodiment, the component package further includes a functional die stack comprising at least the functional semiconductor die as a first functional semiconductor die positioned at the bottom most layer of the functional die stack and one or more additional functional semiconductor die positioned above and bonded to the first functional semiconductor die.

According to one embodiment, the component package includes the functional semiconductor die and one or more additional functional semiconductor dies as a functional semiconductor die stack; and wherein each of the functional semiconductor dies are wire bonded to the electrical traces of the substrate.

According to one embodiment, the substrate is electrically interfaced to a motherboard PCB via solder balls of a ball grid array or alternatively wherein the substrate is to be electrically interfaced to a motherboard PCB via solder balls of a ball grid array by a third party other than the manufacturer of the apparatus; and wherein the motherboard PCB has a coefficient of thermal expansion greater than any of the substrate, the interposer, and the functional semiconductor die.

According to one embodiment, both the functional semiconductor die and the interposer are formed from semiconductor materials including any of Silicon dioxide (SiO2), GaAs, alumina, sapphire, and germanium; and wherein the interposer formed from SiO2, GaAs, alumina, sapphire, and germanium, exhibits a coefficient of thermal expansion different than the functional semiconductor die formed from SiO2, GaAs, alumina, sapphire, and germanium due to one or more geometrically manipulated and non-linear edges of the interposer.

According to one embodiment there is a method for mitigating substrate cracking, the method comprising: fabricating a functional semiconductor die; bonding a bottom surface of the functional semiconductor die to a top surface of an interposer; bonding a bottom surface of the interposer to a top surface of a substrate, the substrate having electrical traces therein; electrically interfacing the functional semiconductor die to the electrical traces of the substrate; and wherein the interposer comprises edges with a coefficient of thermal expansion and modulus which is between a coefficient of thermal expansion and modulus of the substrate and a coefficient of thermal expansion and modulus of the functional semiconductor die.

According to one embodiment, the interposer having edges with the coefficient of thermal expansion and modulus which is between that of the substrate the functional semiconductor die comprises: the edges of the interposer having an average coefficient of thermal expansion and modulus equivalent to (i) the coefficient of thermal expansion and modulus of the substrate and (ii) the coefficient of thermal expansion and modulus of the functional semiconductor die.

According to one embodiment, the edges of the interposer comprise one or more non-linear irregular edges with transitional material properties including at least the coefficient of thermal expansion greater than the coefficient of thermal expansion of the functional semiconductor die and lesser than the coefficient of thermal expansion of the substrate.

According to one embodiment there is a system having an interposer to mitigate substrate cracking, the system comprising: a processor and a memory to execute instructions; a printed circuit board (PCB) motherboard having the processor and the memory mounted thereupon; and a component package mounted to the PCB motherboard, the component package comprising: (i) a substrate having electrical traces therein, (ii) a functional semiconductor die electrically interfaced to the electrical traces of the substrate, (iii) an interposer bonded at a bottom surface to the substrate and bonded at a top surface to the functional semiconductor die, and wherein the interposer comprises edges with a coefficient of thermal expansion and modulus which is between a coefficient of thermal expansion and modulus of the substrate and a coefficient of thermal expansion and modulus of the functional semiconductor die.

According to one embodiment, the substrate of the component package comprises one of: a ball grid array (BGA); an organic substrate; a Land Grid Array (LGA) substrate; and a Printed Circuit Board (PCB) less than 1.5 millimeters thin; and wherein the component package is mounted to the PCB motherboard via solder balls of the substrate.

According to one embodiment, the interposer of the component package having the edges with the coefficient of thermal expansion and modulus which is between that of the substrate the functional semiconductor die comprises: the edges of the interposer having an average coefficient of thermal expansion and modulus equivalent to (i) the coefficient of thermal expansion and modulus of the substrate and (ii) the coefficient of thermal expansion and modulus of the functional semiconductor die.

According to one embodiment, system is embodied within one of: a smart phone; a tablet; a hand-held computing device; a personal computer; or a wearable technology to be worn as a clothing item or an accessory.

According to one embodiment, one or more of the edges of the interposer form a square wave edge of the interposer having material properties between the coefficient of thermal expansion and modulus of the substrate and the coefficient of thermal expansion and modulus of the functional semiconductor die; or alternatively wherein the one or more of the edges of the interposer form a non-square sinusoidal wave edge of the interposer to provide a low stress zone for transitional bulk material properties to increase stress distribution of the substrate.

What is claimed is:

1. An apparatus to mitigate substrate cracking, the apparatus comprising:
a substrate having electrical traces therein;
a functional semiconductor die electrically interfaced to the electrical traces of the substrate;
an interposer bonded at a bottom surface to the substrate and bonded at a top surface to the functional semiconductor die; and
wherein the interposer comprises edges with a coefficient of thermal expansion and modulus which is between a coefficient of thermal expansion and modulus of the substrate and a coefficient of thermal expansion and modulus of the functional semiconductor die.

2. The apparatus of claim 1, wherein the interposer having edges with the coefficient of thermal expansion and modulus which is between that of the substrate the functional semiconductor die comprises:
the edges of the interposer having an average coefficient of thermal expansion and modulus equivalent to (i) the coefficient of thermal expansion and modulus of the substrate and (ii) the coefficient of thermal expansion and modulus of the functional semiconductor die.

3. The apparatus of claim 1, wherein the edges of the interposer comprise one or more non-linear irregular edges with transitional material properties including at least the coefficient of thermal expansion greater than the coefficient of thermal expansion of the functional semiconductor die and lesser than the coefficient of thermal expansion of the substrate.

4. The apparatus of claim 1, wherein the edges of the interposer reduce stress concentrations of the substrate to mitigate cracking of the substrate by distributing stresses over a greater surface area via the interposer.

5. The apparatus of claim 1, wherein one or more of the edges of the interposer form a square wave edge of the interposer having material properties between the coefficient of thermal expansion and modulus of the substrate and the coefficient of thermal expansion and modulus of the functional semiconductor die.

6. The apparatus of claim 1, wherein one or more of the edges of the interposer form a non-square sinusoidal wave edge of the interposer to provide a low stress zone for transitional bulk material properties to increase stress distribution of the substrate.

7. The apparatus of claim 1:
wherein the interposer has one or more non-linear edges forming spaces in the one or more non-linear edges of the interposer and further wherein one or more of the spaces are positioned above a corresponding one or more solder balls affixed to the substrate.

8. The apparatus of claim 1:
wherein the interposer forms a second functional semiconductor die electrically interfaced to the electrical traces of the substrate; and
wherein the interposer which forms the second functional semiconductor die has one or more non-linear edges having one of: a square wave edge, a sinusoidal wave edge, or a non-linear and irregular shaped edge.

9. The apparatus of claim 1, wherein the substrate comprises one of:
a ball grid array (BGA);
an organic substrate;
a Land Grid Array (LGA) substrate; and
a Printed Circuit Board (PCB) less than 1.5 millimeters thin.

10. The apparatus of claim 1, wherein the apparatus embodies a component package comprised of at least the substrate, the interposer, and the functional semiconductor die.

11. The apparatus of claim 10, wherein the component package is backfilled or over-molded with a mold compound.

12. The apparatus of claim 11:
wherein the mold compound exhibits a lower coefficient of thermal expansion than the interposer and a greater coefficient of thermal expansion than the functional semiconductor die; and
wherein the mold compound is of a lower modulus than the interposer.

13. The apparatus of claim 11:
wherein the interposer has one or more non-linear edges forming spaces formed in the one or more non-linear edges of the interposer and further wherein the mold compound partially encapsulates the component package of the substrate, the interposer, and the functional semiconductor die including backfilling with the mold compound the spaces the one or more non-linear edges of the interposer.

14. The apparatus of claim 10, wherein the component package further includes a functional die stack comprising at least the functional semiconductor die as a first functional semiconductor die positioned at the bottom most layer of the functional die stack and one or more additional functional semiconductor die positioned above and bonded to the first functional semiconductor die.

15. The apparatus of claim 10:
wherein the component package includes the functional semiconductor die and one or more additional functional semiconductor dies as a functional semiconductor die stack; and
wherein each of the functional semiconductor dies are wire bonded to the electrical traces of the substrate.

16. The apparatus of claim 1:
wherein the substrate is electrically interfaced to a motherboard PCB via solder balls of a ball grid array or alternatively wherein the substrate is to be electrically interfaced to a motherboard PCB via solder balls of a ball grid array by a third party other than the manufacturer of the apparatus; and
wherein the motherboard PCB has a coefficient of thermal expansion greater than any of the substrate, the interposer, and the functional semiconductor die.

17. The apparatus of claim 1:
wherein both the functional semiconductor die and the interposer are formed from semiconductor materials including any of Silicon dioxide (SiO₂), GaAs, alumina, sapphire, and germanium; and
wherein the interposer formed from SiO₂, GaAs, alumina, sapphire, and germanium, exhibits a coefficient of thermal expansion different than the functional semiconductor die formed from SiO₂, GaAs, alumina, sapphire, and germanium due to one or more geometrically manipulated and non-linear edges of the interposer.

18. A method for mitigating substrate cracking, the method comprising:
fabricating a functional semiconductor die;
bonding a bottom surface of the functional semiconductor die to a top surface of an interposer;
bonding a bottom surface of the interposer to a top surface of a substrate, the substrate having electrical traces therein;
electrically interfacing the functional semiconductor die to the electrical traces of the substrate; and
wherein the interposer comprises edges with a coefficient of thermal expansion and modulus which is between a coefficient of thermal expansion and modulus of the substrate and a coefficient of thermal expansion and modulus of the functional semiconductor die.

19. The method of claim 18, wherein the interposer having edges with the coefficient of thermal expansion and modulus which is between that of the substrate the functional semiconductor die comprises:
the edges of the interposer having an average coefficient of thermal expansion and modulus equivalent to (i) the coefficient of thermal expansion and modulus of the substrate and (ii) the coefficient of thermal expansion and modulus of the functional semiconductor die.

20. The method of claim 18, wherein the edges of the interposer comprise one or more non-linear irregular edges with transitional material properties including at least the coefficient of thermal expansion greater than the coefficient of thermal expansion of the functional semiconductor die and lesser than the coefficient of thermal expansion of the substrate.

21. A system having an interposer to mitigate substrate cracking, the system comprising:
a processor and a memory to execute instructions;
a printed circuit board (PCB) motherboard having the processor and the memory mounted thereupon; and
a component package mounted to the PCB motherboard, the component package comprising:
(i) a substrate having electrical traces therein,
(ii) a functional semiconductor die electrically interfaced to the electrical traces of the substrate,
(iii) an interposer bonded at a bottom surface to the substrate and bonded at a top surface to the functional semiconductor die, and
wherein the interposer comprises edges with a coefficient of thermal expansion and modulus which is between a coefficient of thermal expansion and modulus of the substrate and a coefficient of thermal expansion and modulus of the functional semiconductor die.

22. The system of claim 21, wherein the substrate of the component package comprises one of:
a ball grid array (BGA);
an organic substrate;
a Land Grid Array (LGA) substrate; and
a Printed Circuit Board (PCB) less than 1.5 millimeters thin; and
wherein the component package is mounted to the PCB motherboard via solder balls of the substrate.

23. The system of claim 21, wherein the interposer of the component package having the edges with the coefficient of thermal expansion and modulus which is between that of the substrate the functional semiconductor die comprises:
the edges of the interposer having an average coefficient of thermal expansion and modulus equivalent to (i) the coefficient of thermal expansion and modulus of the substrate and (ii) the coefficient of thermal expansion and modulus of the functional semiconductor die.

24. The system of claim 21, wherein system is embodied within one of:
a smart phone;
a tablet;
a hand-held computing device;
a personal computer; or
a wearable technology to be worn as a clothing item or an accessory.

25. The system of claim 21:
wherein one or more of the edges of the interposer form a square wave edge of the interposer having material properties between the coefficient of thermal expansion and modulus of the substrate and the coefficient of thermal expansion and modulus of the functional semiconductor die; or alternatively
wherein the one or more of the edges of the interposer form a non-square sinusoidal wave edge of the interposer to provide a low stress zone for transitional bulk material properties to increase stress distribution of the substrate.
